(19) United States
(12) Patent Application Publication
(10) Pub. No.: US 2009/0251951 A1
(43) Pub. Date: Oct. 8, 2009

(54) MAGNETORESISTIVE ELEMENT AND MAGNETIC RANDOM ACCESS MEMORY

(76) Inventors: Masatoshi Yoshikawa, Yokohama-shi (JP); Eiji Kitagawa, Sagamihara-shi (JP); Tadaomi Daibou, Kawasaki-shi (JP); Makoto Nagamine, Komae-shi (JP); Tatsuya Kishi, Yokohama-shi (JP); Hiroaki Yoda, Sagamihara-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/409,654

(22) Filed: Mar. 24, 2009

(30) Foreign Application Priority Data
Mar. 27, 2008 (JP) 2008-084939

(51) Int. Cl. G11C 11/00; H01L 29/82; G11C 11/416; G11C 11/14

(52) U.S. Cl. 365/158; 257/421; 365/189.16; 257/E29.323; 365/171

(57) ABSTRACT

A magnetoresistive element includes a foundation layer, a first magnetic layer on the foundation layer, a tunnel barrier layer on the first magnetic layer, and a second magnetic layer on the tunnel barrier layer. The first magnetic layer is made of a ferromagnetic metal containing one or more elements selected from a first group consisting of Co, Fe, and Ni, and one or more elements selected from a second group consisting of Cu, Ag, Au, Pd, Pt, Ru, Rh, Ir, and Os. The foundation layer is made of a metal containing one or more elements selected from a third group consisting of Al, Ni, Co, Fe, Mn, Cr, and V.

### CROSS-REFERENCE TO RELATED APPLICATIONS

This application is based upon and claims the benefit of priority from prior Japanese Patent Application No. 2008-084939, filed Mar. 27, 2008, the entire contents of which are incorporated herein by reference.

### BACKGROUND OF THE INVENTION

1. Field of the Invention

The present invention relates to a magnetoresistive element and magnetic random access memory.

2. Description of the Related Art

Recently, many solid-state memories that record information on the basis of new principles have been proposed. A magnetoresistive random access memory (to be referred to as an MRAM hereinafter) using the tunneling magnetoresistive effect (to be also referred to as a TMR (Tunneling Magneto Resistance) hereinafter) is particularly known as a solid-state magnetic memory. The MRAM uses a magnetoresistive element (to be referred to as a TMR element hereinafter) having the magnetoresistive effect as a memory element of a memory cell. The memory cell stores information in accordance with the magnetization configuration of the TMR element.

The TMR element includes a magnetic free layer in which magnetization is variable, and a magnetic pinned layer in which magnetization is fixed. A low-resistance state is obtained when the magnetization direction in the magnetic free layer is parallel to that in the magnetic pinned layer, and a high-resistance state is obtained when the former is anti-parallel to the latter. The change in resistance state is used for information storage.

A magnetic field writing method is known as a method of writing information in this TMR element. In this method, an interconnection is formed near the TMR element, and a magnetic field generated by an electric current flowing through this interconnection reverses the magnetization in the magnetic free layer of the TMR element. A coercive force Hc of the magnetic free layer of the TMR element increases when the TMR element is downsized in order to a miniaturization of MRAM. In the MRAM using the magnetic field writing method, therefore, an electric current required for write tends to increase as micropatterning advances. This makes it difficult to achieve both a low electric current and memory cell micropatterning for obtaining a large capacity exceeding 1 gigabit.

As a write method of solving this program, a spin injection writing method using SMT (spin-momentum-transfer) has been proposed (see U.S. Pat. No. 6,256,223). In this spin injection writing method, the magnetization configuration of the TMR element having the tunneling magnetoresistance effect is changed (reversed) by supplying an electric current perpendicularly to the film surface of each film forming the TMR element.

In spin injection magnetization reversal, an electric current Ic required for magnetization reversal is often appropriately defined by a current density Jc in many cases. In a TMR element from which the current density Jc meeting the device specifications is obtained, an injection current Ic for reversing magnetization decreases as the conduction area of the electric current decreases if a reversing current density Jc is constant. Accordingly, the electric current Ic decreases as the size of the TMR element decreases. In principle, therefore, the spin injection writing method is superior in scalability to the magnetic field writing method.

In spin injection magnetization reversal, the effective polarizability of the magnetic free layer and magnetic pinned layer determines the reversing current. When the effective polarizability is high, the TMR ratio is high in principle. Therefore, obtaining a high TMR ratio is effective to reduce the spin injection magnetization reversing current.

### BRIEF SUMMARY OF THE INVENTION

A magnetoresistive element according to an aspect of the present invention comprises a foundation layer, a first magnetic layer on the foundation layer, a tunnel barrier layer on the first magnetic layer, and a second magnetic layer on the tunnel barrier layer. The magnetization direction in one of the first and second magnetic layers is invariable, and the magnetization direction in the other is variable. The first magnetic layer is made of a ferromagnetic metal containing one or more elements selected from a first group consisting of Co, Fe, and Ni, and one or more elements selected from a second group consisting of Cu, Ag, Au, Pd, Pt, Ru, Rh, Ir, and Os. The foundation layer is made of a metal containing one or more elements selected from a third group consisting of Al, Ni, Co, Fe, Mn, Cr, and V.

A magnetic random access memory according to an aspect of the present invention comprises the magnetoresistive element, and a write circuit which supplies a write current from one terminal to the other of the magnetoresistive element or vice versa. The write current changes the relationship between the magnetization directions in the first and second magnetic layers.

### BRIEF DESCRIPTION OF THE SEVERAL VIEWS OF THE DRAWING

FIG. 1 is a diagram showing the basic structure of a magnetoresistive element;

FIGS. 2 to 4 are diagrams, each showing a modification example of the basic structure shown in FIG. 1;

FIG. 5 is a diagram showing the crystal structure of a tunnel barrier layer according to an example of the present invention;

FIG. 6 is a diagram showing the crystal structure of a tunnel barrier layer as a comparative example;

FIG. 7 is a diagram showing a bottom free type magnetoresistive element;

FIG. 8 is a diagram showing a top free type magnetoresistive element;

FIG. 9 is a diagram showing a memory cell of a magnetic random access memory;

FIG. 10 is a diagram showing a spin injection magnetic random access memory;

FIG. 11 is a diagram showing the internal structure of a magnetic disc apparatus; and

FIG. 12 is a diagram showing a magnetic head assembly on which a TMR head is mounted.

### DETAILED DESCRIPTION OF THE INVENTION

A magnetoresistive element and a magnetic random access memory of an aspect of the present invention will be described below in detail with reference to the accompanying drawing.

### 1. OUTLINE

In a technique proposed in an example of the present invention, a tunnel barrier layer is given orientation ((001)-plane orientation) by which the (001) plane of the layer is oriented almost perpendicularly to the normal direction of the film surface, thereby achieving a high TMR ratio and making magnetization reversal with a low electric current feasible. In this case, the tunnel barrier layer is preferably an oxide having a tetragonal crystal or cubic crystal as a basic lattice. This is so because the (001) plane of this oxide neutralizes electric charge and hence readily becomes an energy stable plane. The “basic lattice” is also called a Bravais lattice, and is a basic unit. The term “basic lattice” is used as a crystallographic term. For example, the basic lattice of the BCC (Body-Centered Cubic) structure or FCC (Face-Centered Cubic) structure is a cubic crystal.

To give the tunnel barrier layer the orientation as described above, it is particularly important to neutralize the surface potential of the upper surface (surface) of a foundation layer of the tunnel barrier layer when forming the tunnel barrier layer.

In the example of the present invention, neutralization of the surface potential is defined as follows.

A metal material or metal element has affinity to different electrons, i.e., readily attracts electrons. This affinity is represented by an index such as the electro-negativity or ionization tendency.

On the other hand, the standard electrode potential is a potential difference produced when a standard electrode (zero potential) and a different kind of a metal piece are dipped in a standard solution. This concept is also applicable when different metal layers are stacked in contact with each other. A potential difference is produced around the contact interface by the standard electrode potentials of the individual metal layers, and electrons move on the basis of this potential difference. Consequently, the potential difference in the contact interface reduces, but a potential is generated on the surface or in the interface away from the contact interface.

Accordingly, no potential difference is theoretically produced as long as different kinds of metals come in contact with each other. In practice, however, different kinds of materials always come in contact with each other, so a potential difference is always produced in the interface, and a potential is generated on the material surface. In addition, electrons escape from the material surface into the atmosphere or a vacuum. This also generates a potential on the surface.

The “surface potential” is an index indicating the potential state on the surface of a foundation layer of the tunnel barrier layer, i.e., an index representing which of positive or negative electric charge is likely to exist. It is possible to give the tunnel barrier layer the (001)-plane orientation by neutralizing the surface potential.

For example, the surface potential is neutralized if the surface of a foundation layer of the tunnel barrier layer is not charged either positively or negatively. In this case, the tunnel barrier layer orients in the (001) plane and grows on the foundation layer. Also, even when the surface of a foundation layer of the tunnel barrier layer is more or less charged, the surface potential is regarded as being neutralized if the tunnel barrier layer grows as it orients in the (001) plane.

The example of the present invention is characterized by controlling the elements, composition ratios, and thicknesses of layers existing immediately below the tunnel barrier layer, e.g., an interfacial magnetic layer, first magnetic layer, middle foundation layer, and foundation layer, so as to neutralize the surface electric charge of a foundation layer of the tunnel barrier layer.

A magnetoresistive element having a stacked structure including a second magnetic layer/tunnel barrier layer/first magnetic layer will be described below as an example. When using a symbol “/” to indicate a stacked structure of a plurality of layers, the fundamental rule is that a layer described on the left side of the symbol “/” is an upper layer, and a layer described on the right side of the symbol “/” is a lower layer.

When the first magnetic layer is made of a ferromagnetic metal containing one or more elements selected from a first group consisting of Co, Fe, and Ni and one or more elements selected from a second group consisting of Cu, Ag, Au, Pd, Pt, Ru, Rh, Ir, and Os, the standard electrode potential of the first magnetic layer inevitably inclines to the positive side on the basis of the properties of these elements. This is so because each element in the first group has a low negative standard electrode potential, and each element in the second group has a high positive standard electrode potential.

This makes it difficult to give the tunnel barrier layer the orientation by which the (001) plane faces the upper surface of the first magnetic layer.

For example, when using MgO as a representative example of the tunnel barrier layer, if the surface electric charge of the upper surface of the first magnetic layer is positive and MgO flies as it is dissociated into Mg²⁺ and O²⁻, a monoelement layer of O²⁻ is first formed on the first magnetic layer, and then a monoelement layer of Mg²⁺ is stacked on the O²⁻ layer. This gives the tunnel barrier layer the orientation by which the (111) plane faces the upper surface of the first magnetic layer. Similarly, if the surface electric charge of the upper surface of the first magnetic layer is negative, an Mg²⁺ monoelement layer is first formed on the first magnetic layer, and then an O²⁻ monoelement layer is stacked on the Mg²⁺ layer. This gives the tunnel barrier layer the orientation by which the (111) plane faces the upper surface of the first magnetic layer. Consequently, no MgO (001) orientation is constructed, and this makes it impossible to achieve a high TMR ratio and magnetization reversal with a low electric current.

Also, if the surface electric charge of the upper surface of the first magnetic layer is positive when MgO flies as MgO molecules, the O side of the MgO molecule is preferentially adsorbed and stacked on the first magnetic layer. This gives the tunnel barrier layer the orientation by which the (111) plane faces the upper surface of the first magnetic layer. If the surface electric charge of the upper surface of the first magnetic layer is negative, the order of the stacked layers is reversed, but the tunnel barrier layer is given the orientation by which the (111) plane faces the upper surface of the first magnetic layer.

Accordingly, the example of the present invention proposes a method of neutralizing the surface potential of the upper surface (surface) of the first magnetic layer as the foundation of the tunnel barrier layer when forming the tunnel barrier layer.

More specifically, as the foundation of the first magnetic layer, a foundation layer made of a metal containing one or more elements selected from a third group consisting of Al, Ni, Co, Fe, Mn, Cr, and V is newly added.

The surface potential of the upper surface (surface) of this foundation layer inevitably inclines to the negative side on the basis of the properties of these elements. Therefore, the positive electric charge in the first magnetic layer formed on this foundation layer disappears due to the negative electric charge on the upper surface of the foundation layer. This neutralizes the surface potential of the upper surface of the first magnetic layer.

Accordingly, the example of the present invention gives the tunnel barrier layer the (001)-plane orientation, and makes it possible to increase the TMR ratio of the magnetoresistive element and reverse its magnetization with a low electric current.

The above effect notably appears when the magnetoresistive element is a so-called perpendicular magnetization element, i.e., an element having magnetic characteristics by which the residual magnetization in the first magnetic layer points to the second magnetic layer or the opposite side, and that in the second magnetic layer points to the first magnetic layer or the opposite side, and when information is written by the spin injection writing method. Therefore, an object of the example of the present invention is a magnetoresistive element like this.

In the perpendicular magnetization element, the first and second magnetic layers have magnetic anisotropy in a direction in which these layers are stacked.

The perpendicular magnetization element is an element in which the ratio (Mr/Ms) of residual magnetization Mr to saturation magnetization Ms is 0.5 or more with a zero magnetic field on a magnetization-magnetic field (M-H) curve obtained by VSM (Vibrating Sample Magnetometer) measurement or the like.

Even in the perpendicular magnetization element, the residual magnetization direction in the first and second magnetic layers need not be perpendicular to the film surfaces in the direction in which these layers are stacked. That is, the residual magnetization direction in the first and second magnetic layers (the axis of uniaxial magnetic anisotropy: the average value of these layers) need only be 45° (inclusive) to 90° (inclusive) to the film surfaces. “The residual magnetization in the first magnetic layer points to the second magnetic layer or the opposite side, and that in the second magnetic layer points to the first magnetic layer or the opposite side” described above means this condition.

Note that an interfacial magnetic layer different in element or composition ratio from the first magnetic layer may also be formed between the first magnetic layer and tunnel barrier layer. This interfacial magnetic layer is preferably made of a ferromagnetic metal containing one or more elements selected from the first group described previously.

Also, a middle foundation layer may also be formed between the foundation layer and first magnetic layer. This middle foundation layer is preferably made of a metal containing one or more elements selected from the second group described previously.

Furthermore, the middle foundation layer preferably has a cubic crystal or tetragonal crystal as a basic lattice, and has orientation by which the (001) plane is almost perpendicular to the normal direction of the film surface. Each of the foundation layer and first magnetic layer preferably has a cubic crystal or tetragonal crystal as a basic lattice, and has orientation by which the upper surface is the (001) plane. The first magnetic layer favorably has an ordered phase having the L1₀ structure.

More specifically, the first magnetic layer contains one material selected from the group consisting of FePt, FePd, CoPt, and NiPt as a base metal. The tunnel barrier layer is an oxide having a tetragonal crystal or cubic crystal as a basic lattice. An example is MgO.

The magnetoresistive element according to the example of the present invention is effective in a magnetic random access memory that includes a write circuit for supplying a write current from one terminal to the other of the magnetoresistive element or vice versa, and changes the relationship between the magnetization directions in the first and second magnetic layers by the write current.

### 2. EMBODIMENTS

### (1) Basic Structure of Magnetoresistive Element

First, the basic structure of the magnetoresistive element (e.g., a TMR element) according to the example of the present invention will be explained below.

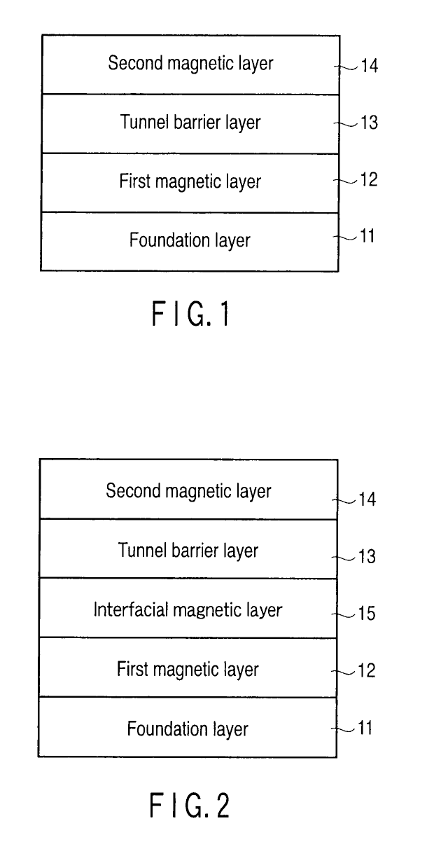

FIG. 1 shows the basic structure of the magnetoresistive element.

A first magnetic layer (e.g., a ferromagnetic layer) 12 is formed on a foundation layer 11, a tunnel barrier layer 13 is formed on the first magnetic layer 12, and a second magnetic layer (e.g., a ferromagnetic layer) 14 is formed on the tunnel barrier layer 13.

The residual magnetization in the first magnetic layer 12 points to the second magnetic layer 14 or the opposite side, and that in the second magnetic layer 14 points to the first magnetic layer 12 or the opposite side. That is, the first and second magnetic layers 12 and 14 are so-called perpendicular magnetization layers having magnetic anisotropy in a direction in which they are stacked.

One of the first and second magnetic layers 12 and 14 is a magnetic pinned layer (reference layer) having an invariable magnetization direction, and the other is a magnetic free layer having a variable magnetization direction. The magnetic pinned layer means a layer in which the magnetization remains unchanged before and after write current flows. The element is called a top free type element when the first magnetic layer 12 is the magnetic pinned layer, and a bottom free type element when the second magnetic layer 14 is the magnetic pinned layer.

The first magnetic layer 12 is made of a ferromagnetic metal containing one or more elements selected from a first group consisting of Co, Fe, and Ni, and one or more elements selected from a second group consisting of Cu, Ag, Au, Pd, Pt, Ru, Rh, Ir, and Os.

The foundation layer 11 is made of a metal containing one element selected from a third group consisting of Al, Ni, Co, Fe, Mn, Cr, and V, or a metal containing two or more elements selected from the third group.

Each of the foundation layer 11 and first magnetic layer 12 preferably has a cubic crystal or tetragonal crystal as a basic lattice, and has orientation by which the upper surface is the (001) plane. The first magnetic layer 12 preferably has an ordered phase having the L1₀ structure.

More specifically, the first magnetic layer 12 contains one material selected from the group consisting of FePt, FePd, CoPt, and NiPt as a base metal. The tunnel barrier layer 13 is an oxide having a tetragonal crystal or cubic crystal as a basic lattice. An example is MgO.

This magnetoresistive element can take two steady states, and stores binary data by making one steady state correspond to data “0”, and the other steady state correspond to data “1”. One of the two steady states is a parallel state in which the magnetization directions in the first and second magnetic layers 12 and 14 are the same, and the other steady state is an antiparallel state in which the magnetization directions in the first and second magnetic layers 12 and 14 are opposite.

The relationship between the magnetization directions in the first and second magnetic layers 12 and 14 is changed by supplying a write current (spin injection current) in a direction in which the first and second magnetic layers 12 and 14 are stacked.

FIG. 2 shows a modification example of the basic structure shown in FIG. 1.

This modification example is characterized in that an interfacial magnetic layer 15 is formed between a first magnetic layer 12 and tunnel barrier layer 13. The rest of the structure is the same as the basic structure shown in FIG. 1.

The interfacial magnetic layer 15 differs from the first magnetic layer 12 in element or composition ratio. The interfacial magnetic layer 15 is made of a ferromagnetic metal containing one element selected from the first group consisting of Co, Fe, and Ni, or a ferromagnetic metal containing two or more elements selected from the first group consisting of Co, Fe, and Ni.

If the lattice misfit between the first magnetic layer 12 and tunnel barrier layer 13 exceeds 5%, the interfacial magnetic layer 15 effectively relaxes and absorbs the lattice misfit.

The lattice misfit is a difference between the lattice size of the material forming the first magnetic layer 12 and that of the material forming the tunnel barrier layer 13.

Note that when the first magnetic layer 12 is the magnetic free layer, the first magnetic layer 12 and interfacial magnetic layer 15 integrally reverse magnetization.

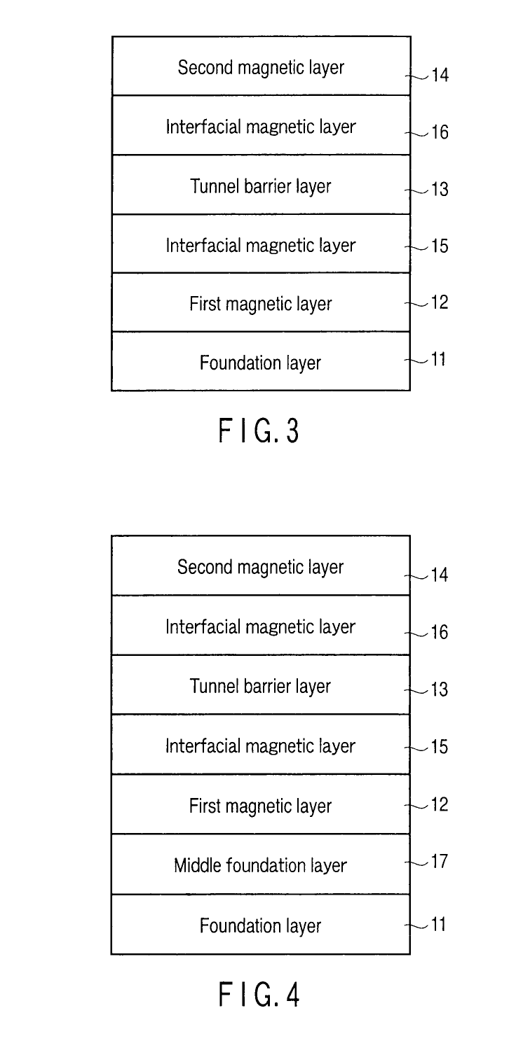

FIG. 3 shows another modification example of the basic structure shown in FIG. 1.

This modification example is characterized in that an interfacial magnetic layer 15 is formed between a first magnetic layer 12 and tunnel barrier layer 13, and an interfacial magnetic layer 16 is formed between the tunnel barrier layer 13 and a second magnetic layer 14. The rest of the structure is the same as the basic structure shown in FIG. 1.

The function and effect of the interfacial magnetic layer 15 have already been explained in the modification example shown in FIG. 2, so a repetitive explanation will be omitted.

The interfacial magnetic layer 16 differs from the second magnetic layer 14 in element or composition ratio. The interfacial magnetic layer 16 is made of a ferromagnetic metal containing one element selected from the first group consisting of Co, Fe, and Ni, or a ferromagnetic metal containing two or more elements selected from the first group consisting of Co, Fe, and Ni.

If the lattice misfit between the tunnel barrier layer 13 and second magnetic layer 14 exceeds 5%, the interfacial magnetic layer 16 effectively relaxes and absorbs the lattice misfit.

Note that when the second magnetic layer 14 is the magnetic free layer, the second magnetic layer 14 and interfacial magnetic layer 16 integrally reverse magnetization.

When the first magnetic layer 12 is the magnetic free layer, the first magnetic layer 12 and interfacial magnetic layer 15 integrally reverse magnetization. Note that it is also possible to use a structure from which the first magnetic layer 12 is omitted.

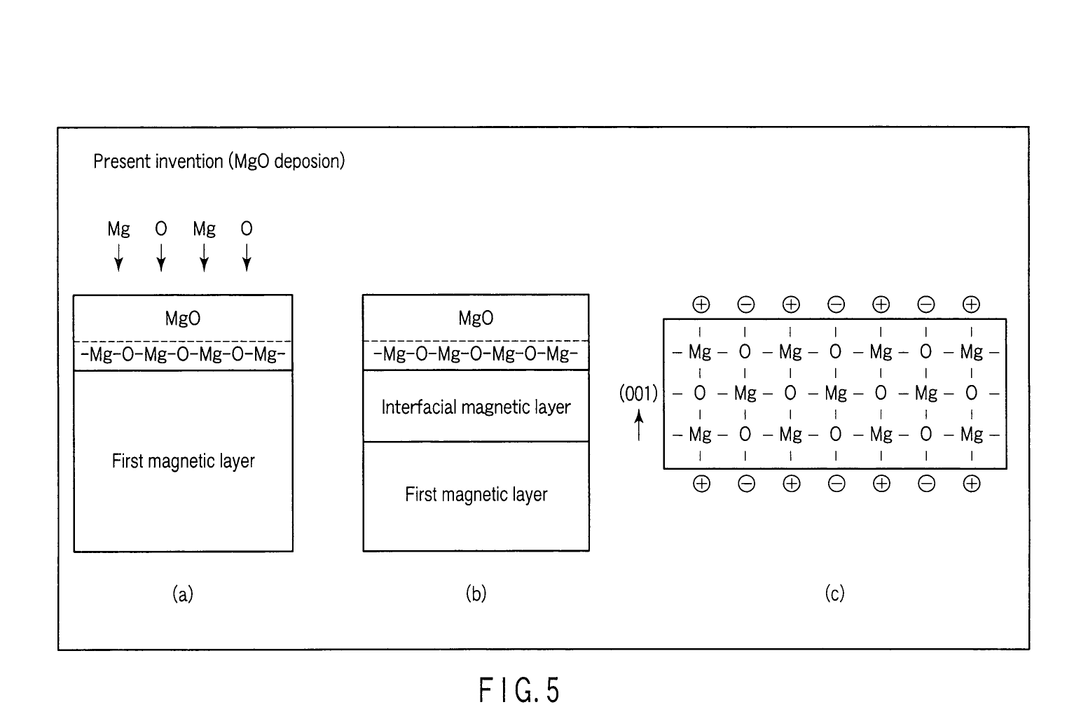

FIG. 4 shows still another modification example of the basic structure shown in FIG. 1.

This modification example is characterized in that an interfacial magnetic layer 15 is formed between a first magnetic layer 12 and tunnel barrier layer 13, an interfacial magnetic layer 16 is formed between the tunnel barrier layer 13 and a second magnetic layer 14, and a middle foundation layer 17 is formed between a foundation layer 11 and the first magnetic layer 12. The rest of the structure is the same as the basic structure shown in FIG. 1.

The functions and effects of the interfacial magnetic layers 15 and 16 have been explained in the modification examples shown in FIGS. 2 and 3, so a repetitive explanation will be omitted.

The middle foundation layer 17 is made of a metal containing one element selected from the second group consisting of Cu, Ag, Au, Pd, Pt, Ru, Rh, Ir, and Os, or a metal containing two or more elements selected from the second group consisting of Cu, Ag, Au, Pd, Pt, Ru, Rh, Ir, and Os.

The middle foundation layer 17 preferably has a cubic crystal or tetragonal crystal as a basic lattice, and has orientation by which the (001) plane is almost perpendicular to the normal direction of the film surface, i.e., the (001) plane faces the upper surface of the foundation layer 11.

If the lattice misfit between the foundation layer 11 and first magnetic layer 12 exceeds 5%, the middle foundation layer 17 effectively relaxes and absorbs the lattice misfit.

### (2) Adjustment of Surface Potential

The formation of a high-TMR-ratio tunnel barrier layer by adjustment of the surface potential will now be explained.

In the present invention, the tunnel barrier layer is an oxide having a tetragonal crystal or cubic crystal as a basic lattice. Most oxides couple with oxygen ions having divalent negative electric charge by ion coupling. In an oxide having a tetragonal crystal or cubic crystal as a basic lattice, the electric charge is neutralized in a unit cell. In this unit cell, therefore, the electric charge is neutral on the (001) plane.

On the other hand, when forming an oxide as a thin film, the oxide has a marked tendency to grow its crystal to neutralize the surface electric charge, and expose the most stable plane to the surface. This tendency is particularly notable in an ion-coupled oxide having the NaCl structure.

From the foregoing, it is readily possible to imagine that when forming a thin oxide film, this thin oxide film initially grows so as to neutralize the surface electric charge of a foundation layer. When forming the tunnel barrier layer, therefore, the control of the surface electric charge of a foundation layer functioning as the foundation is a very important factor for growing a (001)-oriented tunnel barrier layer.

Generally, an oxide having the NaCl structure has the simplest crystal structure and is readily controllable. As this oxide having the NaCl structure, MgO is an optimum oxide applicable to the present invention. This is so because the (001) plane of an oxide having the NaCl structure represented by MgO connects to a metal having a body-centered cubic structure and containing Fe, Co, or Ni, thereby achieving a spin filter effect caused by the band structure, and exhibiting a high TMR ratio.

Even in MgO as described above, the (001) plane is the most stable plane in respect of electric charge, so the electric charge is neutralized in the (001) plane. This is so because equal amounts of Mg and O alternately exist.

In other orientation planes, the existing ratios of Mg and O are different. In the (111) plane, for example, a monoelement layer made of Mg alone and a monoelement layer made of O alone are alternately stacked. Accordingly, only one of Mg and O is exposed to the surface. Also, in the (011) plane, the atomic existing ratio of Mg to O slightly deviates from 1:1.

Other examples of the NaCl-structure oxide are CaO, SrO, BaO, TiO, VO, and mixtures made of two or more compounds selected from the group consisting of CaO, SrO, BaO, TiO, VO, and MgO. Any of these compounds and mixtures can be applied as the tunnel barrier layer according to the present invention.

These compounds and mixtures are the same from the viewpoint of charge stability obtained by the above-mentioned orientation plane.

When the film thickness of a thin film of the NaCl-structure oxide described above is 10 nm or more, the influence in the interface with a foundation layer decreases and the original stable (001) plane is exposed to the surface in most cases. However, the resistance must be decreased in order to use the element as a magnetoresistive element to which spin injection magnetization reversal is applied. This makes it necessary to decrease the film thickness of the tunnel barrier layer (to, e.g., less than 10 nm).

Especially when using MgO that is most promising as the tunnel barrier layer, a film thickness of 2 nm or less is required. To orient this thin film in the (001) plane, it is necessary to neutralize the surface electric charge of a lower electrode as the foundation of the tunnel barrier layer (MgO).

The surface potential of the first magnetic layer (or interfacial magnetic layer) in the initial growth process of the tunnel barrier layer (MgO) will be explained below.

In the magnetoresistive element according to the example of the present invention, a foundation layer, first magnetic layer, tunnel barrier layer, and second magnetic layer are stacked in this order on a semiconductor substrate.

The first magnetic layer is made of a ferromagnetic metal containing one or more elements selected from a first group consisting of Co, Fe, and Ni, and one or more elements selected from a second group consisting of Cu, Ag, Au, Pd, Pt, Ru, Rh, and Ir, and has a positive standard electrode potential. That is, the first magnetic layer has a large affinity to electrons and hence readily attracts electrons.

Before forming the tunnel barrier layer, therefore, a material (the foundation layer) having a negative standard electrode potential is brought into contact with this material having a positive standard electrode potential in advance.

The foundation layer is made of a metal containing one element selected from a third group consisting of Al, Ni, Co, Fe, Mn, Cr, and V, or a metal containing two or more elements selected from the third group, and has a negative standard electrode potential. That is, the foundation layer has a small affinity to electrons and hence readily releases electrons.

In this case, a potential difference is produced in the contact interface between the foundation layer and first magnetic layer, and electrons flow toward the material (first magnetic layer) having a positive standard electrode potential. The effect of this electron (electric charge) transfer reduces the positive surface potential of the first magnetic layer. The surface electric charge of the first magnetic layer is ideally neutral (neither negative nor positive).

Note that the surface potential of the first magnetic layer is controlled by the difference between the standard electrode potentials of the foundation layer and first magnetic layer, and the difference between the thicknesses of the foundation layer and first magnetic layer.

When forming the tunnel barrier layer (MgO) as shown in, e.g., FIG. 5, therefore, the surface electric charge of the first magnetic layer is neutral, so the tunnel barrier layer can be oriented in the (001) plane.

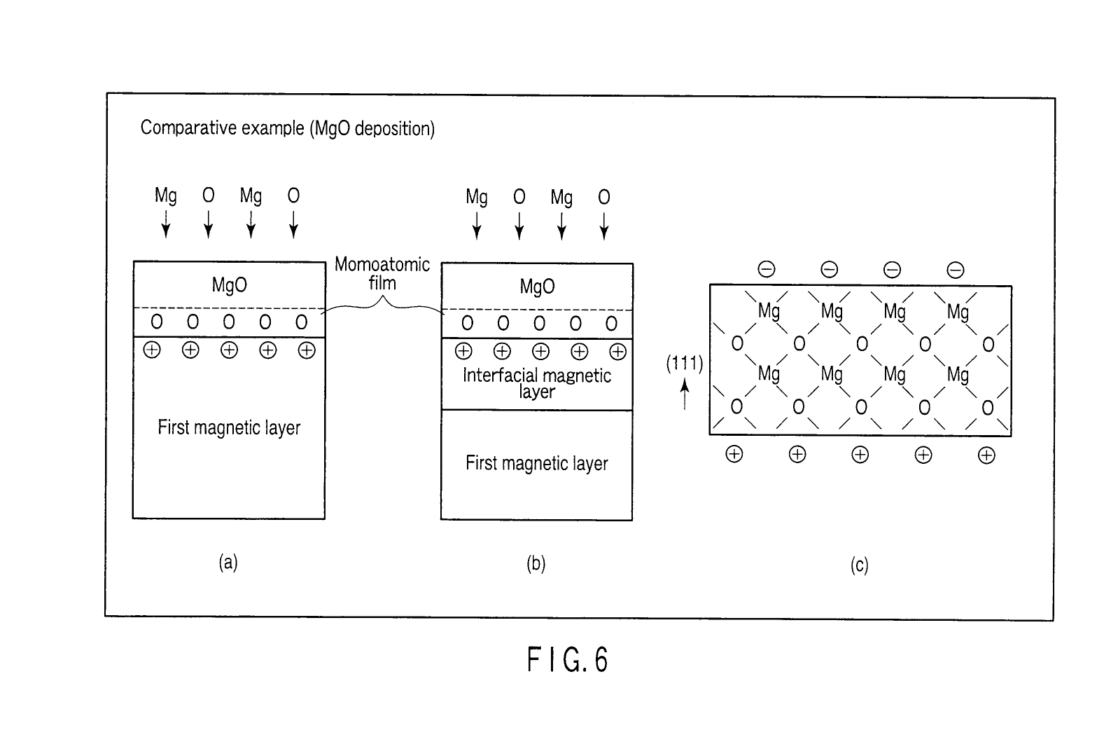

Assume that the tunnel barrier layer is formed on the first magnetic layer without forming the foundation layer proposed in the example of the present invention. When the tunnel barrier layer is made of, e.g., MgO, as indicated by (a) in FIG. 6, oxygen ions O²⁻ having negative electric charge are initially attracted to the surface of the first magnetic layer and remain on the surface by adsorption. Consequently, the tunnel barrier layer sometimes has a stacked structure including O/Mg/O/ . . . /Mg/O/the first magnetic layer. Alternatively, although not shown in FIG. 6, O does not remain by adsorption but dissociates and scatters in some cases, thereby forming a stacked structure including O/Mg/O/ . . . /Mg/the first magnetic layer.

That is, since the amount of oxygen atoms or Mg atoms is excessive in the first layer of the tunnel barrier layer, the tunnel barrier layer is given orientation by which the (111) plane faces the upper surface of the first magnetic layer. In addition, the ratio at which the upper surface of the first magnetic layer (interfacial magnetic layer) in contact with the tunnel barrier layer couples with oxygen atoms increases, and this oxidizes the upper surface of the first magnetic layer. As a result, a high-resistance, low-TMR magnetoresistive element is obtained.

In the present invention, however, the foundation layer as described above is formed as the foundation of the first magnetic layer. Accordingly, no such problem as described above arises, and a high TMR ratio can be achieved by orienting the tunnel barrier layer in the (001) plane.

In the example of the present invention, an interfacial magnetic layer may also be formed between the first magnetic layer and tunnel barrier layer. The interfacial magnetic layer differs from the first magnetic layer in element or composition ratio, is made of a ferromagnetic metal containing one element selected from the first group consisting of Co, Fe, and Ni, or a ferromagnetic metal containing two or more elements selected from the first group, and has a low negative standard electrode potential. That is, the interfacial magnetic layer has a small affinity to electrons and hence readily releases electrons.

Accordingly, a (001)-oriented tunnel barrier layer can also be formed by forming the interfacial magnetic layer on the first magnetic layer, and controlling the surface potential of the interfacial magnetic layer.

Examples of the metal material to be used as the interfacial magnetic layer are fcc (face-centered cubic lattice)-CoFe, bcc (body-centered cubic lattice)-FeCo, bcc-FeNi, fcc-NiFe, a (amorphous)-CoFeB, and a-CoFeNiB.

The interfacial magnetic layer has the effect of relaxing and absorbing the lattice misfit between the first magnetic layer and tunnel barrier layer. That is, the interfacial magnetic layer is used as a lattice relaxing layer. The interfacial magnetic layer is essential if the lattice misfit between the first magnetic layer and tunnel barrier layer exceeds 5%.

When the influence of the surface potential alone is taken into consideration, a minimum thickness of the interfacial magnetic layer is preferably 0.1 nm or more. The interfacial magnetic layer achieves the surface electric charge neutralizing effect even when the layer is not a completely continuous film in respect of composition. To allow the interfacial magnetic layer to function as a lattice relaxing layer, however, a thickness of 0.5 nm or more is necessary. On the other hand, the thickness of the interfacial magnetic layer is favorably 5 nm or less in order to give the interfacial magnetic layer the same magnetic anisotropy as that of the first magnetic layer.

When the interfacial magnetic layer is formed on the first magnetic layer, the surface potential of the interfacial magnetic layer can also be neutralized by the effect of charge transfer between the first magnetic layer and interfacial magnetic layer. The surface potential of the interfacial magnetic layer is controlled by the standard electrode potentials and thicknesses of the foundation layer and first magnetic layer, and the standard electrode potential and thickness of the interfacial magnetic layer itself.

To maintain so-called perpendicular magnetization of the first magnetic layer, the thickness of the interfacial magnetic layer is preferably 3 nm or less. If the thickness of the interfacial magnetic layer exceeds 3 nm, the perpendicular magnetization characteristics of the first magnetic layer deteriorate. Perpendicular magnetization is defined as magnetization by which the residual magnetization ratio: Mr (residual magnetization)/Ms (saturation magnetization) is 0.5 or more.

In the example of the present invention, a middle foundation layer may also be formed between the foundation layer and first magnetic layer. The middle foundation layer is made of a metal containing one element selected from the second group consisting of Cu, Ag, Au, Pd, Pt, Ru, Rh, Ir, and Os, or a metal containing two or more elements selected from the second group.

Examples of a binary ferromagnetic metal as the base of the first magnetic layer are an FePt metal and FePd metal having the face-centered cubic structure or face-centered tetragonal structure, a CoPt metal, a CoPd metal, an NiPt metal, an NiPd metal, and a CoPt metal having the closest packed structure.

It is also possible to use any of ternary, quaternary, and quinary metals obtained by appropriately mixing the above-mentioned binary ferromagnetic metals, as the base metal of the material of the first magnetic layer.

Examples of the ternary ferromagnetic metal are an FePdPt metal, FeRhPd metal, FeRhPt metal, FeNiPd metal, FeNiPt metal, FeCoPd metal, and FeCoPt metal.

The standard electrode potentials of monoelement metals are as follows. Examples of a metal having a positive standard electrode potential are Cu=0.52 (eV), Ag=0.80 (eV), Au=1.68 (eV), Pd=0.99 (eV), Pt=1.19 (eV), Ru>0 (eV), Rh>0 (eV), Ir=1.00 (eV), and Os>0 (eV). Examples of a metal having a negative standard electrode potential are Co=−0.28 (eV), Fe=−0.44 (eV), and Ni=−0.25 (eV).

Each of the standard electrode potentials of Ru, Rh, and Os is a numerical value estimated from the numerical value of the electron affinity. The standard electrode potential is calculated by distributing the standard electrode potentials of individual elements in accordance with the composition ratio. For example, a standard electrode potential E_{AB} of a binary metal AₓB₍₁₋ₓ₎ is represented by the following equation by using standard electrode potentials E_{A} and E_{B} of the individual elements.

A metal used in the foundation layer according to the example of the present invention, i.e., a metal containing one element selected from the third group consisting of Al, Ni, Co, Fe, Mn, Cr, and V or a metal containing two or more elements selected from the third group has a negative standard electrode potential. Also, Al, Ni, and Co have the face-centered cubic structure, and Fe, Mn, Cr, and V have the body-centered cubic structure.

The standard electrode potentials of these monoelement metals are that Al=−1.66 (eV), Ni=−0.25 (eV), Co=−0.28 (eV), Fe=−0.44 (eV), Mn=−1.18 (eV), Cr=−0.91 (eV), and V=−0.88 (eV).

There are other elements for which the standard electrode potential of a monoelement metal is negative.

The elements are Ti=−1.63 (eV), Zr=−1.53 (eV), Mg=−2.37 (eV), Zn=−0.76 (eV), Cd=−0.40 (eV), Sn=−0.14 (eV), Pb=−0.13 (eV), Ta<0 (eV), Nb<0 (eV), W<0 (eV), and Mo<0 (eV).

The standard electrode potential of each of Ta, Nb, W, and Mo is a numerical value estimated from the electron affinity.

The method of calculating the standard electrode potential of the foundation layer made of a binary or higher-order metal is the same as that for the first magnetic layer.

Examples of the metal to be used as the foundation layer according to the example of the present invention are fcc-FeNi, bcc-FeCr, fcc-FeMn, bcc-FeCo, and fcc-CoFe.

The bcc structure or fcc structure is favorable as the foundation layer.

Also, when the foundation layer has orientation by which the upper surface is the (001) plane, the first magnetic layer or middle foundation layer formed on the foundation layer also has orientation by which the upper surface is the (001) plane. This is convenient to finally orient the tunnel barrier layer in the (001) plane.

Furthermore, the perpendicular magnetic characteristics of the first magnetic layer improve as the (001) orientation improves.

To adjust the lattice constant and standard electrode potential of the first magnetic layer, it is also possible to add a slight amount of, e.g., Ta, W, Nb, or Mo having a large lattice constant or Ti, Zr, Hf, Y, or La having the hexagonal closest packed structure (hcp) to the first magnetic layer.

The “slight amount addition” herein mentioned is defined as the addition of 10 at % or less.

This slight amount addition need only be performed near the interface between the first magnetic layer and interfacial magnetic layer, or the interface between the middle foundation layer and first magnetic layer. “Near the interface” herein mentioned is defined as the range of 1 nm or less from the interface between the two layers.

Furthermore, the lattice constant of the foundation layer can also be adjusted by giving composition gradation to the layer in the direction of thickness. Examples of the candidate are an NiTa metal, NiW metal, AlCu metal, and NiMo metal.

In the example of the present invention, an oxide, a nitride, and a metal compound (e.g., a metal silicide) of a semiconductor element such as Si, Ge, or Ga each have a neutral electron affinity and zero standard electrode potential. That is, the standard electrode potential can be reset to zero by an oxide, nitride, or metal compound. Any of these materials functions as a potential resetting layer.

Accordingly, when an oxide layer (e.g., a silicon oxide layer) exists immediately below the foundation layer, the electric charge of this oxide layer is neutral.

In the example of the present invention, this potential resetting layer preferably exists immediately below the foundation layer.

Structural design of the standard electrode potential for resetting the surface potential of the foundation of the tunnel barrier layer before the tunnel barrier layer is formed will be explained below.

Assume that the magnetoresistive element has a stacked structure of the interfacial magnetic layer/first magnetic layer/middle foundation layer/foundation layer, and the tunnel barrier layer is formed on the interfacial magnetic layer.

Let t₁, t₂, t₃, and t₄ be the thicknesses of the foundation layer, middle foundation layer, first magnetic layer, and interfacial magnetic layer, respectively. Also, let E₁, E₂, E₃, and E₄ be the standard electrode potentials of the foundation layer, middle foundation layer, first magnetic layer, and interfacial magnetic layer, respectively.

The standard electrode potential of each layer is calculated by equation (1) presented earlier.

A minimum necessary condition for neutralizing the surface potential of the interfacial magnetic layer is represented by

[symbol]

E=E₁·t₁+E₂·t₂+E₃·t₃·+E₄·t₄=0

where E₁·t₁<0, E₂·t₂>0, and E₃·t₃>0.

E₄·t₄ is finely adjusted.

Note that the standard electrode potential of the interfacial magnetic layer as the uppermost layer sometimes has excess influence compared to those of other layers. In practice, when the composition and thickness of the first magnetic layer are determined, E₃ and t₃ are fixed. When the optimum composition and thickness of the middle foundation layer are determined by taking account of E₃ and t₃, E₂ and t₂ are determined.

For example, when the interfacial magnetic layer is CoFeB (1 nm), the first magnetic layer is FePt (3 nm), the FePt composition is 50:50 at %, the middle foundation layer is Pt (3 nm), and the foundation layer is Cr, the parameters are t₂=3 (nm), t₃=3 (nm), t₄=1 (nm), E₁=−0.91 (eV), E₂=1.19 (eV), E₃=0.815 (eV), and E₄ to 0 (eV). Accordingly, the minimum necessary film thickness t₁ of the Cr foundation layer is

t1=−(E₂·t₂+E₃·t₃·+E₄·t₄)/E1=6.6 nm

In practice, therefore, the thickness of Cr as the foundation layer must be 6.6 nm or more when fine adjustment is included.

### (3) Relationship Between Tunnel Barrier Layer and Interfacial Magnetic Layer

All embodiments of the present invention use the tunnel barrier layer. An oxide having the NaCl structure is used as the tunnel barrier layer. Practical examples of the material are BeO, CaO, MgO, SrO, BaO, and TiO as oxides of Be, Ca, Mg, Sr, Ba, and Ti, respectively. The tunnel barrier layer may also be a mixed crystal of two or more materials selected from the group consisting of these oxides.

When the simplicity of formation and processability of the tunnel barrier layer are taken into consideration, MgO is practical as the material of the tunnel barrier layer and achieves the highest MR ratio.

The tunnel barrier layer having the NaCl structure can achieve a high TMR ratio when forming a matching interface that is epitaxial in the (001) plane with interfacial magnetic layer having the body-centered cubic structure (bcc) or face-centered cubic structure (fcc), e.g., Fe_{(1-x-y)}CoₓNi_{y} (0≦x≦1, 0≦y≦1, and 0≦x+y≦1).

A high TMR ratio is obtained when the interfacial magnetic layer has the bcc structure. In this case, the following relationships preferably hold in the (001) plane of the tunnel barrier layer and the (001) plane of the interfacial magnetic layer having the body-centered cubic structure (bcc).
Tunnel barrier layer [100] direction//bcc-structure interfacial magnetic layer [110] direction
Tunnel barrier layer (001) plane//bcc-structure interfacial magnetic layer (001) plane

Also, when the interfacial magnetic layer has the fcc structure, the following relationships preferably hold in the (001) plane of the tunnel barrier layer and the (001) plane of the fcc interfacial magnetic layer.
Tunnel barrier layer [100] direction//fcc-structure interfacial magnetic layer [110] direction
Tunnel barrier layer (001) plane//fcc-structure interfacial magnetic layer (001) plane

A symbol // means “parallel”.

The lattice mismatching in the interface between the tunnel barrier layer and interfacial magnetic layer is favorably reduced in order to maintain the orientation relationship and crystal orientation relationship described above.

In addition, when the lattice matching in the interface is good, the connection of the band structures in an electron state of the interfacial magnetic layer and tunnel barrier layer improves, and coherent electron tunneling occurs. Ideally, when coherent electron tunneling occurs, the resistance value when the magnetoresistive element is in a low-resistance state (the magnetization directions in two magnetic layers are parallel) decreases, so a high TMR ratio can be expected. To achieve this coherent tunneling, the lattice matching in the two interfaces of the tunnel barrier layer having the NaCl structure are necessary.

In an ordinary magnetoresistive element, it is very difficult to grow a tunnel barrier layer having the NaCl structure on the (100) plane of a magnetic layer having the bcc structure, such that the tunnel barrier layer orients in the (100) plane. In this case, the orientation of the tunnel barrier layer has a mixed-phase state in which the (100) and (111) planes are mixed, so (100)-oriented crystal grains and (111)-oriented crystal grains randomly exist.

This relaxes the increase in energy caused by the interface mismatching between the tunnel barrier layer and the (100) plane of the magnetic layer as the foundation of the tunnel barrier layer. Since this increases misfit transition caused by the lattice mismatching in the interface between the tunnel barrier layer and the magnetic layer as the foundation of the tunnel barrier layer, a sheet resistance RA of the magnetoresistive element increases.

On a foundation layer having an amorphous structure, the crystal of the tunnel barrier layer having the NaCl structure often grows such that the (100) plane preferentially orients. This is so because the surface of a thin film having an amorphous structure has the effect of relaxing the electric charge or potential toward a neutral side.

It is, however, impossible to completely neutralize the surface of the foundation layer, and complete neutralization requires adjustment performed by mixing elements having positive and negative standard electrode potentials.

To give the interfacial magnetic layer according to the example of the present invention the function of the foundation layer of the tunnel barrier layer, it is favorable to add a semimetal element such as B, P, S, or C, N (nitrogen), or a semiconductor element such as Si, Ge, or Ga to Fe_{(1-x-y)}CoₓNi_{y} (0≦x≦1, 0≦y≦1, and 0≦x+y≦1) having the bcc structure.

Since B presumably has a low positive standard electrode potential, a low negative standard electrode potential of FeCoNi can be neutralized by adding B to the FeCoNi metal. The FeCoNi metal to which B is thus added is crystallized by annealing, and a bcc-structure phase deposits on the surface.

The thickness of the interfacial magnetic layer is optimized within the range of 0.1 nm (inclusive) to 5 nm (inclusive).

If the thickness of the interfacial magnetic layer is less than 0.1 nm, it is impossible to increase the TMR and decrease the sheet resistance RA. If the thickness exceeds 5 nm, spin torque is hardly generated, so the magnetic free layer does not perform spin injection magnetization reversal any longer.

From the viewpoints of electron conduction and spin torque, therefore, the thickness of the interfacial magnetic layer is optimized within the range of 0.1 nm (inclusive) to 5 nm (inclusive) so that the thickness of the magnetic free layer including the interfacial magnetic layer can be decreased to 5 nm or less.

Also, the thickness of the interfacial magnetic layer is preferably 3 nm or less in order to maintain the perpendicular magnetization characteristics of the first magnetic layer. If the thickness exceeds 3 nm, the residual magnetization ratio (Mr/Ms ratio) becomes lower than 0.5 in many cases, and this makes the perpendicular magnetization characteristics difficult to maintain.

Furthermore, the interfacial magnetic layer has the effect of relaxing and absorbing the lattice misfit between the first magnetic layer and tunnel barrier layer. That is, the interfacial magnetic layer is also used as a lattice relaxing layer. The interfacial magnetic layer is essential if the lattice misfit between the first magnetic layer and tunnel barrier layer exceeds 5%.

A thickness of 0.5 nm or more is necessary, however, in order to well achieve the function of the lattice relaxing layer.

Accordingly, an optimum film thickness of the interfacial magnetic layer is 0.5 nm (inclusive) to 3 nm (inclusive).

Also, the interfacial magnetic layer preferably contains 50 at % or more of one or more elements selected from Fe, Co, and Ni. This is so because magnetization sometimes disappears if the ratio of these elements contained in the interfacial magnetic layer is less than 50 at %.

For example, the magnetization in the interfacial magnetic layer disappears if 50 at % or more of Cr, V, Mn, or the like are added to the interfacial magnetic layer. In this case, the polarizability of the interfacial magnetic layer is highly likely to decrease or disappear. Accordingly, even if this decreases the sheet resistance RA of the magnetoresistive element, no MR ratio can be observed any longer.

(4) Relationship between Interfacial Magnetic Layer/First Magnetic Layer/Middle Foundation Layer/Foundation layer

An example of the material that achieves perpendicular magnetization in the first magnetic layer is a face-centered tetragonal structure ferromagnetic metal having the Llo ordered structure and containing one or more elements selected from the group consisting of Fe, Co, and Ni (to be referred to as an element A hereinafter), and one or more elements selected from the group consisting of Pt and Pd (to be referred to as an element B hereinafter).

Representative examples of the ferromagnetic metal having the L1₀ ordered structure are an L1₀-FePt metal, L1₀-FePd metal, L1₀-CoPt metal, and L1₀-NiPt metal. A metal containing at least two of these metals, e.g., an L1₀-FeCoNiPtPd metal is also a ferromagnetic metal having the L1₀ ordered structure.

The first magnetic layer contains one binary metal selected from the group consisting of FePt, FePd, CoPt, and NiPt as a base metal. These base metals are mixtures in which the composition ratio is almost 1:1. The “base metal” herein mentioned is one binary metal selected from the group consisting of FePt, FePd, CoPt, and NiPt, or a ternary or higher-order metal containing 50 at % or more of the binary metal.

Also, the first magnetic layer is preferably the L1₀-FePd metal in order to decrease damping, and preferably the L1₀-CoPt metal, L1₀-CoNiPt metal, L1₀-FeRhPt metal, or L1₀-FeRhPd metal in order to decrease the saturation magnetization Ms.

When the composition ratio of the elements A and B is represented by a composition formula A₍₁₀₀₋ₓ₎Bₓ, x must be 30 at % (inclusive) to 70 at % (inclusive) in order to obtain the L1₀ ordered structure. The element A can be partially substituted with Cu or Zn. The element B can be partially substituted with Au, Ag, Ru, Rh, Ir, Os, or a rare-earth element (e.g., Nd, Sm, Gd, or Tb).

This makes it possible to adjust and optimize the saturation magnetization Ms and magnetocrystalline anisotropic energy Ku of the magnetic free layer having perpendicular magnetization.

The ferromagnetic AB metal having the L1₀ ordered structure has the face-centered tetragonal (fct) structure. Ordering gives the metal a high magnetocrystalline anisotropic energy of about 1×10⁷ erg/cc in the [001] direction.

Accordingly, favorable perpendicular magnetization characteristics can be obtained by preferentially orienting the (001) plane. Also, the saturation magnetization falls within the range of about 600 to 1,200 emu/cm³. The saturation magnetization and magnetocrystalline anisotropic energy decrease when a substituting element is added to the element A or B described above.

The above-mentioned AB metal as the first magnetic layer having the L1₀ ordered structure is a metal or monoelement metal having a (001) surface and mainly containing Fe, Co, or Ni. In addition, the (001) plane of the interfacial magnetic layer having a cubic crystal or tetragonal crystal as a basic lattice readily preferentially grows on the AB metal.

The (001) surface of the first magnetic layer having the L1₀ structure phase can be confirmed by the (002) peak found when 2θ=45° to 50° in θ-2θ scan of X-ray diffraction. To improve the perpendicular magnetization characteristics, the half-width of a rocking curve of the (002) diffraction peak must be 10° or less, preferably, 5° or less.

The existence of the L1₀ ordered structure phase and the preferential orientation of the (001) plane can be confirmed by the existence of the (001) diffraction peak found when 2θ=20° to 25° in θ-2θ scan of X-ray diffraction.

These diffraction images resulting from the (001) and (002) planes can also be confirmed by electron beam diffraction analysis.

The first magnetic layer is formed as it is preferentially oriented in the (001) plane, on the middle foundation layer or foundation layer preferentially oriented in the (001) plane.

Examples of the monoelement metal of the middle foundation layer are Pt, Pd, Au, Ag, Cu, Rh, Ir, Ru, and Os. Examples of the metal are a PtPd metal, PdCu metal, and AuCu metal. The middle foundation layer is inserted to reduce the lattice misfit between the (001)-oriented first magnetic layer and (001)-oriented foundation layer.

Also, from the viewpoint of magnetic characteristics, when the foundation layer is a ferromagnetic material, antiferromagnetic material, or ferrimagnetic material, the middle foundation layer must be inserted in order to separate the magnetizations in the foundation layer and first magnetic layer.

The middle foundation layer basically has fcc, but sometimes has an ordered phase having the CsCl structure such as the AuCu metal.

The middle foundation layer is preferentially oriented in the (001) plane. On the (001)-oriented middle foundation layer, the crystal of the first magnetic layer can be grown as it is preferentially oriented in the (001) plane.

In the present invention, the foundation layer is preferably nonmagnetic. In this case, it is sometimes possible to omit the middle foundation layer.

Furthermore, since the element used in the middle foundation layer has a positive standard electrode potential, the thickness of the foundation layer required to neutralize the surface potential before the tunnel barrier layer is formed may increase. When this is taken into consideration, the middle foundation layer is favorably omitted if it can be omitted.

The following crystal orientation relationships hold between the middle foundation layer having the fcc structure and the first magnetic layer having the L1₀ structure.
L1₀-structure first magnetic layer [100] direction//fcc-structure middle foundation layer [100] direction
L1₀-structure first magnetic layer (001) plane//fcc-structure middle foundation layer (001) plane

In addition, in the (001) interface between the L1₀-structure first magnetic layer and fcc-structure middle foundation layer, the lattice mismatch between them is preferably 3% or less. The lattice misfit is further decreased to about 1% by adjustment by metallizing the middle foundation layer. This adjustment can be performed by using, e.g., the AuCu metal or PdCu metal.

The following crystal orientation relationships hold between the fcc-structure middle foundation layer and fcc-structure foundation layer.
fcc-structure middle foundation layer [100] direction//fcc-structure foundation layer [100] direction
fcc-structure middle foundation layer (001) plane//fcc-structure foundation layer (001) plane

Furthermore, the following crystal orientation relationships hold between the fcc-structure middle foundation layer and bcc-structure foundation layer.
fcc-structure middle foundation layer [100] direction//bcc-structure foundation layer [100] direction
fcc-structure middle foundation layer (001) plane//bcc-structure foundation layer (001) plane
   (5) Relationships between Second Magnetic Layer and Interfacial Magnetic Layer

The second magnetic layer having perpendicular magnetization will be explained below. The definition of “perpendicular magnetization” or “magnetization practically perpendicular to the film surface” is that the ratio (Mr/Ms) of the residual magnetization Mr to the saturation magnetization Ms with a zero magnetic field is 0.5 or more on a magnetization-magnetic field (M-H) curve obtained by VSM (Vibrating Sample Magnetometer) measurement or the like.

The characteristic length along which the spin torque acts is about 1.0 nm. Examples of the material that achieves perpendicular magnetization are a CoPt metal, CoCrPt metal, and CoCrPtTa metal having the hexagonal closed pack (hcp) structure or face-centered cubic (fcc) structure. To exhibit magnetization perpendicular to the film surface, (001)-plane orientation is necessary in the hcp structure, and (111)-plane orientation is necessary in the fcc structure. When any of these materials is used, a phase transition layer having the CsCl ordered structure readily orients in the (110) plane.

Another example of the material that achieves perpendicular magnetization is an RE-TM metal made of a rare-earth metal (to be referred to as RE hereinafter) and an element (to be referred to as TM hereinafter) selected from Co, Fe, and Ni, and having an amorphous structure. The RE-TM metal can be manipulated by the amount of the RE element such that the net saturation magnetization changes from negative to positive. A point at which net saturation magnetization Ms-net is zero is called a compensation point, and a composition at this point is called a compensation point composition. In this compensation point composition, the ratio of the RE element is 25 to 50 at %.

Still another example of the material that achieves perpendicular magnetization is an artificial lattice type perpendicular magnetization film that is a multilayered stack including a magnetic layer containing an element selected from Co, Fe, and Ni, and a nonmagnetic metal layer containing Pd, Pt, Au, Rh, Ir, Os, Ru, Ag, or Cu. An example of the material of the magnetic layer is a Co_{(100-x-y)}FeₓNi_{y} metal (0≦x≦100, 0≦y≦100). A CoFeNiB amorphous metal obtained by adding 10 to 25 at % of B to the CoFeNi metal is also an example of the material.

The thickness of the magnetic layer is optimized from 0.1 to 1 nm. The thickness of the nonmagnetic layer is optimized within the range of 0.1 to 3 nm. The crystal structure of the artificial lattice film can be any of the hcp structure, fcc structure, and bcc structure. The orientation of the film is such that a portion of the film preferably orients in the (111) plane, (110) plane, and (001) plane when the film has the fcc structure, bcc structure, and hcp structure, respectively. The orientation is obtained from X-ray diffraction and electron beam diffraction.

Still another example of the material that achieves perpendicular magnetization is an fct-structure ferromagnetic metal having the Llo ordered structure, and made of one or more elements selected from Fe and Co (to be referred to as an element A hereinafter) and one or more elements selected from Pt and Pd (to be referred to as an element B hereinafter).

Representative examples of the L1₀-ordered-structure ferromagnetic metal are an L1₀-FePt metal, L1₀-FePd metal, and L1₀-CoPt metal. An L1₀-FeCoPtPd metal containing these metals is also an example. When the composition ratio of the element A to the element B is represented by a composition formula A₍₁₀₀₋ₓ₎Bₓ (x is at %), x must be 30 at % (inclusive) to 70 at % (inclusive) in order to obtain the L1₀ ordered structure. The element A can be partially substituted with Ni or Cu. The element B can be partially substituted with Au, Ag, Ru, Rh, Ir, Os, or a rare-earth element (e.g., Nd, Sm, Gd, or Tb).

This makes it possible to adjust and optimize the saturation magnetization Ms and magnetocrystalline anisotropic energy (uniaxial magnetic anisotropic energy) Ku of the magnetic free layer having perpendicular magnetization.

The ferromagnetic AB metal having the L1₀ ordered structure has the face-centered tetragonal (fct) structure. Ordering gives the metal a high magnetocrystalline anisotropic energy of about 1×10⁷ erg/cc in the [001] direction. Accordingly, favorable perpendicular magnetization characteristics can be obtained by preferentially orienting the (001) plane. Also, the saturation magnetization falls within the range of about 600 to 1,200 emu/cm³. When a substituting element is added to the element A or B, the saturation magnetization and magnetocrystalline anisotropic energy decrease. On the (001) plane of the ferromagnetic AB metal having the L1₀ ordered structure, a bcc-structure metal mainly containing Fe, Cr, V or the like often grows as it preferentially orients in the (001) plane.

The (001)-plane preferential orientation of the fct-FePt metal can be confirmed by the (002) peak found when 2θ=45° to 50° in θ-2θ scan of X-ray diffraction. To improve the perpendicular magnetization characteristics, the half-width of a rocking curve of the (002) diffraction peak must be 10° or less, preferably, 5° or less.

The presence/absence of the L1₀ ordered structure phase and the (001)-plane preferential orientation can be confirmed by the (001) diffraction peak found when 2θ=20° to 25° in θ-2θ scan of X-ray diffraction.

These diffraction images resulting from the (001) and (002) planes can also be confirmed by electron beam diffraction analysis or the like.

### (6) Design of Magnetic Free Layer and Magnetic Pinned Layer

The thermal stability of the magnetic free layer and magnetic pinned layer will now be explained.

The first and second magnetic layers have large Ku values, and improve the thermal stability of magnetization of a lower electrode. The magnetocrystalline anisotropic energy Ku is higher than that of the interfacial magnetic layer, i.e., 1×10⁶ erg/cc or more. The first and second magnetic layers couple with the interfacial magnetic layer by exchange coupling, and make the magnetization direction in the interfacial magnetic layer perpendicular.

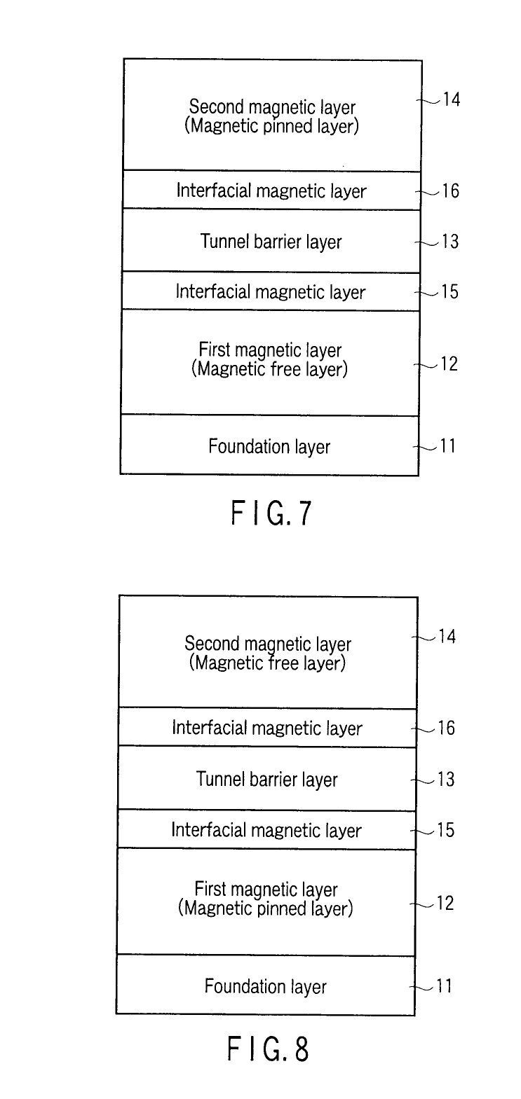

For example, when a first magnetic layer 12 is the magnetic free layer as shown in FIG. 7, the total thickness of the first magnetic layer 12 and an interfacial magnetic layer 15 is practically set to 5 nm or less from the viewpoint of spin injection magnetization reversal. This is so because if the total thickness exceeds 5 nm, the spin torque does not well function in the magnetic layer made up of the magnetic free layer 12 and interfacial magnetic layer 15, so the first magnetic layer 12 does not reverse magnetization by spin injection any longer.

On the other hand, the total thickness of a second magnetic layer 14 as the magnetic pinned layer and an interfacial magnetic layer 16 is determined under the condition that no magnetization reversal occurs due to a reaction produced when magnetization reversal occurs in the magnetic free layer 12.

Accordingly, letting Mₛ-free and t_{free} be the saturation magnetization and thickness, respectively, of the magnetic free layer 12, and Mₛ-reference and t_{reference} be the saturation magnetization and thickness, respectively, of the magnetic pinned layer 14, a relation (A) below holds.

M_{s-free}×t_{free}<M_{s-reference}×t_{reference} (A)

Also, when the second magnetic layer 14 is the magnetic free layer as shown in FIG. 8, the total thickness of the second magnetic layer 14 and interfacial magnetic layer 16 is practically preferably 5 nm or less from the viewpoint of spin injection magnetization reversal, for the same reason as that of the case shown in FIG. 7.

On the other hand, the total thickness of the first magnetic layer 12 as the magnetic pinned layer and the interfacial magnetic layer 15 is determined under the condition that no magnetization reversal occurs due to a reaction produced when magnetization reversal occurs in the magnetic free layer 14.

Accordingly, letting M_{s-free} and t_{free} be the saturation magnetization and thickness, respectively, of the magnetic free layer 14, and M_{s-reference} and t_{reference} be the saturation magnetization and thickness, respectively, of the magnetic pinned layer 12, the relationship indicated by the relation (A) presented above is obtained as in the case shown in FIG. 7.

### 3. EXAMPLES OF EXPERIMENT

Experimental examples of the magnetoresistive element according to the example of the present invention will be explained below.

The following magnetoresistive films (samples) were formed, and the crystallinity of each tunnel barrier layer was verified. A numerical value indicated in the parentheses after each layer is the thickness (design value) of each layer when it was formed. Each sample was annealed at an appropriate temperature for an appropriate time after formation.

### Comparative Example 1

The magnetoresistive element had a cap layer/TbCoFe ferromagnetic layer (30 nm)/CoFeB interfacial layer (1 nm)/MgO tunnel barrier layer (1.5 nm)/CoFeB interfacial magnetic layer (1 nm)/L1₀-FePt ferromagnetic layer (5 nm)/Pt middle foundation layer (3 nm)/nitride resetting layer (20 nm) in this order from the upper layer side.

### Experimental Example 1

The magnetoresistive element had a cap layer/TbCoFe ferromagnetic layer (30 nm)/MgO tunnel barrier layer (1.5 nm)/CoFeB interfacial magnetic layer (1 nm)/L1₀-FePt ferromagnetic layer (5 nm)/Pt middle foundation layer (3 nm)/Fe foundation layer (10 nm)/Cr foundation layer (10 nm)/NiTa foundation layer (20 nm)/Ta foundation layer (5 nm)/thermal oxide Si layer (potential resetting layer) in this order from the upper layer side.

### Experimental Example 2

The magnetoresistive element had a cap layer/L1₀-FePt ferromagnetic layer (3 nm)/MgO tunnel barrier layer (1.5 nm)/CoFeB interfacial magnetic layer (2 nm)/L1₀-FePt ferromagnetic layer (10 nm)/Pt middle foundation layer (3 nm)/Cr foundation layer (20 nm)/NiTa foundation layer (20 nm)/Ta foundation layer (5 nm)/thermal oxide Si layer (potential resetting layer) in this order from the upper layer side.

In each sample, the nitride resetting layer and thermal oxide Si layer functioned as potential resetting layers for preventing generation of the surface electric charge. Also, after each layer was formed, vacuum annealing was performed to optimize the TMR characteristics and magnetic characteristics.

Sectional TEM observation was performed on the three samples described above, thereby evaluating and examining the crystallinity of each MgO tunnel barrier layer.

In Comparative Example 1, the MgO tunnel barrier layer was found to be amorphous by X-ray diffraction because no clear (001) diffraction peak was observed. Therefore, the crystallinity of the MgO tunnel barrier layer deteriorated. This significantly increased the sheet resistance RA, and decreased the TMR ratio accordingly.

By contrast, in each of Experimental Examples 1 and 2, good (001) orientation of the MgO tunnel barrier layer was confirmed by X-ray diffraction. Also, in these experimental examples, the sheet resistance RA significantly decreased, and accordingly the TMR ratio significantly increased, compared to Comparative Example 1. Especially in Experimental Example 2, a high TMR close to 100% was obtained.

Note that when the foundation layer, middle foundation layer, interfacial magnetic layer, and ferromagnetic layer have a stacked structure including a plurality of layers, the standard electrode potentials of all the layers are taken into account.

### 4. APPLICATION EXAMPLES

Application examples of the present invention will be explained below.

### (1) Spin Injection Magnetic Random Access Memory

The magnetoresistive element according to the example of the present invention is particularly effective in a spin injection magnetic random access memory which has a write circuit for supplying a write current from one terminal to the other of the magnetoresistive element or vice versa, and in which the write current changes the relationship between the magnetization directions in first and second magnetic layers.

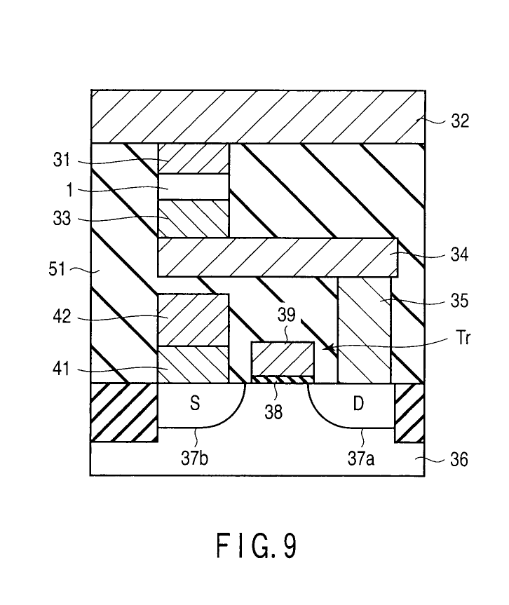

FIG. 9 shows a memory cell of the spin injection magnetic random access memory.

The upper end of a magnetoresistive element 1 is connected to an upper bit line 32 via an upper electrode 31. The lower end of the magnetoresistive element 1 is connected to a drain diffusion layer 37a of a select transistor Tr via a lower electrode 33, extraction electrode 34, and plug 35.

A source diffusion layer 37b of the select transistor Tr is connected to a lower bit line 42 via a plug 41.

A gate electrode (word line) 39 is formed on a gate insulating film 38 on a semiconductor substrate (channel region) 36 between the drain diffusion layer 37a and source diffusion layer 37b.

In the memory cell having this structure, an interlayer dielectric film (e.g., silicon nitride) formed immediately below the extraction electrode 34 functions as a potential resetting layer. Also, the lower electrode 33 and extraction electrode 34 are each made of a general interconnection material such as W, Al, AlCu, or Cu.

In this case, at least the first magnetic layer of the magnetoresistive element 1, the foundation layer according to the example of the present invention, the lower electrode 33, and the extraction electrode 34 exist immediately below the tunnel barrier layer of the magnetoresistive element 1.

In the example of the present invention, therefore, the elements, composition ratios, and thicknesses of the first magnetic layer of the magnetoresistive element 1, the foundation layer according to the example of the present invention, the lower electrode 33, and the extraction electrode 34 are determined so as to neutralize the surface electric charge of the foundation layer of the tunnel barrier layer of the magnetoresistive element 1.

Note that at least one of the lower electrode 33 and extraction electrode 34 may also be omitted.

For example, when omitting the lower electrode 33, the magnetoresistive element 1 is formed on the extraction electrode 34. When omitting the extraction electrode 34, the lower electrode 33 is formed on the plug 35. When omitting the lower electrode 33 and extraction electrode 34, the magnetoresistive element 1 is formed on the plug 35.

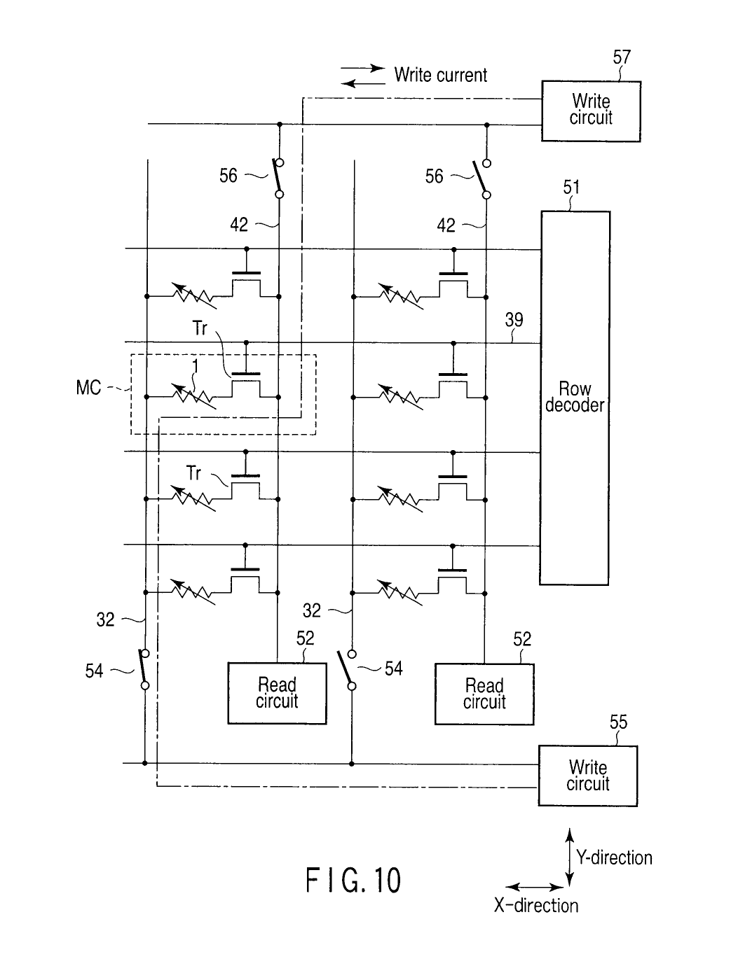

FIG. 10 shows a memory cell array including the memory cell shown in FIG. 9.

In FIG. 10, the same reference numerals as in FIG. 9 denote the same elements.

Memory cells MC each have, e.g., the structure show in FIG. 9, and are arranged in the form of an array.

Word lines 39 run in the X-direction, and are each connected to the gate electrode of the select transistor Tr of the memory cell MC. One end of each word line 39 is connected to a row decoder 51. The row decoder 51 selects the word lines 39.

One end of each bit line 32 is connected to a write circuit 55 via a switching circuit 54 such as a transistor. The write circuit 55 has a current source/sink circuit for generating/absorbing a write current (spin injection current).

Similarly, one end of each bit line 42 is connected to a write circuit 57 via a switching circuit 56 such as a transistor. The write circuit 57 has a current source/sink circuit for generating/absorbing a write current (spin injection current).

The other end of the bit line 42 is connected to a read circuit 52. The read circuit 52 includes a current source for generating a read current, a sense amplifier, and the like.

When writing data, the switching circuits 54 and 56 connected to a selected memory cell MC as a write object are turned on, and other switching circuits are turned off. Also, the select transistor Tr in the selected memory cell MC is turned on.

Then, a write current is supplied to the selected memory cell MC in a direction corresponding to the write data. For example, when writing data “1”, the write current is supplied from the write circuit (source side) 55 to the write circuit (sink side) 57. When writing data “0”, the write current is supplied from the write circuit (source side) 57 to the write circuit (sink side) 55.

The write current is an electric current having a pulse width of, e.g., a few ns to a few us.

When reading data, the switching circuit 54 connected to a selected memory cell MC as a read object is turned on, and other switching circuits are turned off. Also, the select transistor Tr in the selected memory cell MC is turned on.

Then, a read current is supplied to the selected memory cell MC.

The value of the read current is made much smaller than that of the write current so as not to cause any magnetization reversal (switching) by the read current. The pulse width of the read current is preferably smaller than that of the write current.

### (2) Magnetic Disc Apparatus

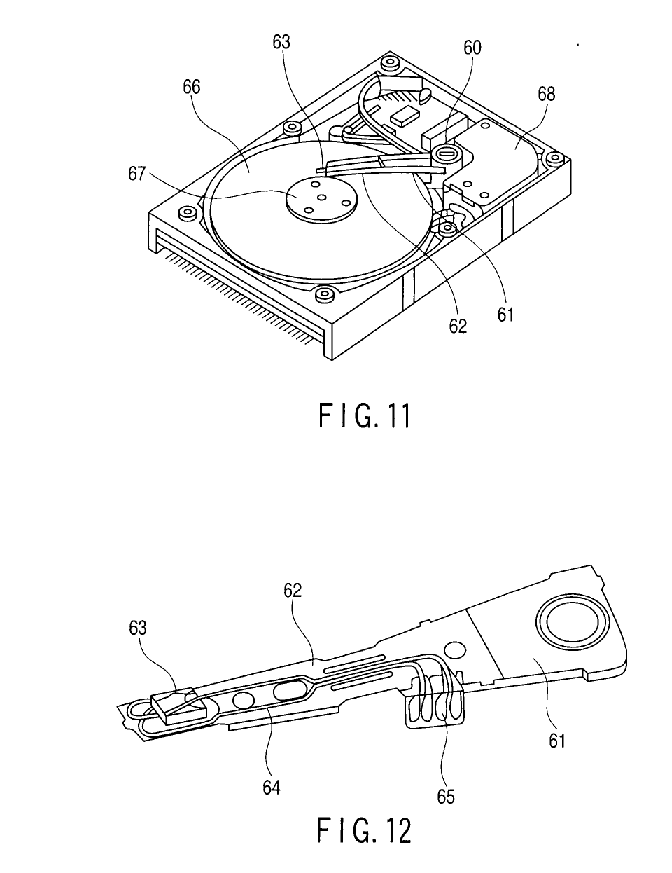

FIG. 11 shows the internal structure of a magnetic disc apparatus. FIG. 12 shows a magnetic head assembly on which a TMR head is mounted.

An actuator arm 61 has a hole to be fixed to a fixing shaft 60 in the magnetic disc apparatus. A suspension 62 is connected to one end of the actuator arm 61.

A head slider 63 on which the TMR head is mounted is attached to the distal end of the suspension 62. Also, a lead line 64 for data write/read is formed on the suspension 62.

One end of the lead line 64 is electrically connected to the electrode of the TMR head incorporated into the head slider 63.

The TMR head includes the magnetoresistive element according to the example of the present invention.

The other end of the lead line 64 is connected to an electrode pad 65.

A magnetic disc 66 is attached to a spindle 67, and driven by a motor in accordance with a control signal from a driving controller.

The head slider 63 floats by a predetermined amount when the magnetic disc 66 rotates. In this state, data is recorded or reproduced by using the TMR head.

The actuator arm 61 has a bobbin for holding a driving coil. A voice coil motor 68 as a kind of a linear motor is connected to the actuator arm 61.

The voice coil motor 68 has a magnetic circuit including the driving coil wound around the bobbin of the actuator arm 61, and a permanent magnet and counter yoke opposed to each other so as to sandwich the coil between them.

The actuator arm 61 is held by ball bearings formed in upper and lower portions of the fixing shaft 60, and driven by the voice coil motor 68.

### (3) Others

The spin injection magnetic random access memory and magnetic disc apparatus have been explained as application examples of the present invention. However, the example of the present invention is also applicable to general memories using the TMR effect.

### 5. ADVANTAGES

The present invention can implement a spin injection writing type magnetoresistive element and magnetic random access memory capable of achieving a high TMR ratio and magnetization reversal with a low electric current.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetoresistive element comprising:
a foundation layer;
a first magnetic layer on the foundation layer;
a tunnel barrier layer on the first magnetic layer; and
a second magnetic layer on the tunnel barrier layer,
wherein a magnetization direction in one of the first magnetic layer and the second magnetic layer is invariable, and a magnetization direction in the other is variable,
the first magnetic layer is made of a ferromagnetic metal containing one or more elements selected from a first group consisting of Co, Fe, and Ni, and one or more elements selected from a second group consisting of Cu, Ag, Au, Pd, Pt, Ru, Rh, Ir, and Os, and
the foundation layer is made of a metal containing one or more elements selected from a third group consisting of Al, Ni, Co, Fe, Mn, Cr, and V.

2. The element according to claim 1, wherein the tunnel barrier layer is an oxide having one of a tetragonal crystal structure and a cubic crystal structure as a basic lattice, and a portion which orients as its (001) plane is parallel to the film plane.

3. The element according to claim 1, further comprising an interfacial magnetic layer formed between the first magnetic layer and the tunnel barrier layer, and different from the first magnetic layer in one of a element and a composition ratio,
wherein the interfacial magnetic layer is made of a ferromagnetic material containing one or more elements selected from the first group, and
a surface potential of the interfacial magnetic layer is neutralized by elements, composition ratios, and thicknesses of the foundation layer, the first magnetic layer, and the interfacial magnetic layer.

4. The element according to claim 1, further comprising a middle foundation layer formed between the foundation layer and the first magnetic layer,
wherein the middle foundation layer is made of a metal containing one or more elements selected from the second group, and
a surface potential of the first magnetic layer is neutralized by elements, composition ratios, and thicknesses of the foundation layer, the middle foundation layer, and the first magnetic layer.

5. The element according to claim 4, wherein the middle foundation layer has one of a cubic crystal and a tetragonal crystal as a basic lattice, and has (001) orientation.

6. The element according to claim 1, further comprising:
an interfacial magnetic layer formed between the first magnetic layer and the tunnel barrier layer, and different from the first magnetic layer in one of a element and a composition ratio; and
a middle foundation layer formed between the foundation layer and the first magnetic layer,
wherein the interfacial magnetic layer is made of a ferromagnetic material containing one or more elements selected from the first group,
the middle foundation layer is made of a metal containing one or more elements selected from the second group, and
a surface potential of the interfacial magnetic layer is neutralized by elements, composition ratios, and thicknesses of the foundation layer, the middle foundation layer, the first magnetic layer, and the interfacial magnetic layer.

7. The element according to claim 6, wherein the middle foundation layer has one of a cubic crystal and a tetragonal crystal as a basic lattice, and has (001) orientation.

8. The element according to claim 1, wherein the foundation layer and the first magnetic layer each have one of a cubic crystal and a tetragonal crystal as a basic lattice, and have (001) orientation.

9. The element according to claim 1, wherein the first magnetic layer has an ordered phase having an Llo structure.

10. The element according to claim 1, wherein the first magnetic layer contains one material selected from the group consisting of FePt, FePd, CoPt, and NiPt as a base metal.

11. The element according to claim 1, wherein the tunnel barrier layer is made of MgO.

12. The element according to claim 1, wherein the first magnetic layer and the second magnetic layer have magnetic anisotropy in a direction in which the first magnetic layer and the second magnetic layer are stacked.

13. The element according to claim 1, wherein a magnetization direction in the first magnetic layer is invariable, and a magnetization direction in the second magnetic layer is variable.

14. The element according to claim 1, wherein a magnetization direction in the first magnetic layer is variable, and a magnetization direction in the second magnetic layer is invariable.

15. A magnetic random access memory comprising:
a memory cell which includes the magnetoresistive element according to claim 1; and
a write circuit which supplies a write current from one terminal to the other of the magnetoresistive element or vice versa,
wherein the write current changes a relationship between magnetization directions in the first magnetic layer and the second magnetic layer.

16. The memory according to claim 15, wherein the memory cell is comprised of the magnetoresistive element and a select transistor connected in series.

17. The memory according to claim 15, wherein the write circuit includes a current source circuit which generates the write current, and a current sink circuit which absorbs the write current.

18. The memory according to claim 15, wherein the relationship between the magnetization directions in the first magnetic layer and the second magnetic layer is changed by generating spin torque by the write current.

19. The memory according to claim 15, further comprising an interfacial magnetic layer formed between the first magnetic layer and the tunnel barrier layer, and different from the first magnetic layer in one of a element and a composition ratio,
wherein the interfacial magnetic layer is made of a ferromagnetic material containing one or more elements selected from the first group, and
a surface potential of the interfacial magnetic layer is neutralized by elements, composition ratios, and thicknesses of the foundation layer, the first magnetic layer, and the interfacial magnetic layer.

20. The memory according to claim 15, further comprising a middle foundation layer formed between the foundation layer and the first magnetic layer,
wherein the middle foundation layer is made of a metal containing one or more elements selected from the second group, and
a surface potential of the first magnetic layer is neutralized by elements, composition ratios, and thicknesses of the foundation layer, the middle foundation layer, and the first magnetic layer.
